(19) United States
(12) Patent Application Publication
(10) Pub. No.: US 2026/0279791 A1
(43) Pub. Date: Sep. 17, 2026

(54) CATHODE ACTIVE MATERIAL AND LITHIUM-ION BATTERY

(71) Applicant: TOYOTA JIDOSHA KABUSHIKI KAISHA, Toyota-shi (JP)

(72) Inventors: Ryosuke OHSAWA, Okazaki-shi (JP); Yuji MAHARA, Seto-shi, Aichi-ken (JP)

(73) Assignee: TOYOTA JIDOSHA KABUSHIKI KAISHA, Toyota-shi (JP)

(21) Appl. No.: 19/443,413

(22) Filed: Jan. 8, 2026

(30) Foreign Application Priority Data
Mar. 14, 2025 (JP) 2025-041380

(51) Int. Cl. H01M 4/525; C30B 29/22; H01M 4/02; H01M 10/054

(52) U.S. Cl. CPC H01M 4/525; C30B 29/22; H01M 10/054; H01M 2004/021

(57) ABSTRACT

The present disclosure provides a cathode active material for use in a lithium-ion battery. The cathode active material includes crystalline primary particles containing Li, Ni, Mn, and O. The cathode active material is a single-crystal active material formed of the primary particles. The primary particles have, as a main phase, a crystal structure belonging to the space group R-3m. When observed with a transmission electron microscope, the primary particles have a first exposed surface other than a (003) plane. The amount of Mn in a surface region of the first exposed surface is defined as X and the amount of Mn in a bulk region located closer to the center of the primary particle than the surface region is defined as Y, and X and Y satisfy 1.1≤X/Y.

### CROSS-REFERENCE TO RELATED APPLICATION

This application claims priority to Japanese Patent Application No. 2025-041380 filed on Mar. 14, 2025. The disclosure of the above-identified application, including the specification, drawings, and claims, is incorporated by reference herein in its entirety.

### BACKGROUND

### 1. Technical Field

The present disclosure relates to cathode active materials and lithium-ion batteries.

### 2. Description of Related Art

Battery development has been active in recent years. For example, in the automotive industry, lithium-ion batteries for use in battery electric vehicles (BEVs), plug-in hybrid electric vehicles (PHEVs), and hybrid electric vehicles (HEVs) have been actively developed. Various studies have been conducted on cathode active materials for lithium-ion batteries.

For example, Japanese Unexamined Patent Application Publication No. 2023-516229 (JP 2023-516229 A) discloses a lithium-nickel-cobalt-manganese composite oxide (NCM-based active material) as a cathode active material. Japanese Unexamined Patent Application Publication No. 2023-500940 (JP 2023-500940 A) discloses a precursor for a cathode active material for secondary batteries. The precursor includes primary particles containing crystal grains oriented such that a (001) plane forms an angle of 20° to 160° with the longitudinal direction of the primary particle. Japanese Unexamined Patent Application Publication No. 2017-033641 (JP 2017-033641 A) discloses a cathode active material for non-aqueous electrolyte secondary batteries that contains a lithium-nickel-cobalt-manganese composite oxide containing tungsten.

### SUMMARY

From the viewpoint of improving battery performance, it is desirable for a battery to exhibit good capacity retention even after repeated charge and discharge cycles. The present disclosure has been made in view of such circumstances, and a primary object thereof is to provide a cathode active material that can improve the capacity retention of a lithium-ion battery.

(1) A cathode active material for use in a lithium-ion battery, the cathode active material including primary particles that are crystalline, the primary particles containing Li, Ni, Mn, and O, wherein:
the cathode active material is a single-crystal active material constituted of the primary particles;
the primary particles have, as a main phase, a crystal structure belonging to the space group R-3m;
when observed with a transmission electron microscope, the primary particles have a first exposed surface other than a (003) plane; and
the amount of Mn in a surface region of the first exposed surface is defined as X and the amount of Mn in a bulk region located closer to the center of the primary particle than the surface region is defined as Y, and X and Y satisfy 1.1≤X/Y.

(2) The cathode active material according to (1), wherein:
when observed with a transmission electron microscope, the primary particles have a second exposed surface of the (003) plane; and
the amount of Mn in a surface region of the second exposed surface is defined as P and the amount of Mn in a bulk region located closer to the center of the primary particle than the surface region is defined as Q, and P and Q satisfy 0.95≤P/Q≤1.05.

(3) The cathode active material according to (1) or (2), wherein X and Y satisfy X/Y≤2.0.

(4) The cathode active material according to any one of (1) to (3), wherein the average particle size of the primary particles is 0.5 μm or more.

(5) The cathode active material according to any one of (1) to (4), wherein the primary particles have a composition represented by LiₓNiₐCo_{b}Mn_{c}O_{y} (where 0.1≤x≤1.5, 0.5≤a≤1.0, 0≤b≤0.3, 0<c≤0.3, a+b+c=1.0, and 1.5≤y≤2.1).

(6) A lithium-ion battery comprising: a cathode active material layer; an anode active material layer; and an electrolyte layer disposed between the cathode active material layer and the anode active material layer,
wherein the cathode active material layer contains the cathode active material according to any one of (1) to (5).

The present disclosure can provide a cathode active material that can improve the capacity retention of a lithium-ion battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1A is a diagram illustrating a crystal plane of a primary particle according to the present disclosure;

FIG. 1B is a diagram illustrating a crystal plane of a primary particle according to the present disclosure;

FIG. 1C is a diagram illustrating a crystal plane of a primary particle according to the present disclosure;

FIG. 2 is a diagram illustrating a surface region and a bulk region of a primary particle according to the present disclosure; and

FIG. 3 is a schematic sectional view illustrating a lithium-ion battery according to the present disclosure.

### DETAILED DESCRIPTION OF EMBODIMENTS

The cathode active material and the lithium-ion battery according to the present disclosure will now be described in detail. The drawings referenced below are provided for illustration purposes, and the sizes and shapes of the components may be exaggerated in some cases for better understanding.

### A. Cathode Active Material

The cathode active material of the present disclosure is a cathode active material for use in lithium-ion batteries, and includes crystalline primary particles containing Li, Ni, Mn, and O. The cathode active material is a single-crystal active material formed of such primary particles. The primary particles have, as a main phase, a crystal structure belonging to the space group R-3m. When observed with a transmission electron microscope, the primary particles have a first exposed surface other than a (003) plane. The amount of Mn (hereinafter also referred to as “Mn amount”) in a surface region of the first exposed surface is defined as X and the amount of Mn in a bulk region located closer to the center of the primary particle than the surface region is defined as Y, and X and Y satisfy 1.1≤X/Y.

In the present disclosure, since the Mn amount in the surface region of the first exposed surface other than the (003) plane of the primary particle is higher than the Mn amount in the bulk region (1.1≤X/Y), the cathode active material can improve the capacity retention of a battery.

As described above, NCM-based active materials are known as cathode active materials. In the course of investigating NCM-based active materials, the inventors found that increasing the proportion of Ni in the active material improves the battery's discharge capacity (initial discharge capacity), but leads to a decrease in reversible capacity and therefore a decline in capacity retention with repeated charge and discharge cycles. The inventors examined this issue by focusing on crystal planes other than the (003) plane (for example, a (101) plane and a (104) plane) through which lithium ions are inserted and extracted in the cathode active material. As a result, the inventors found that increasing the amount of Mn and thus relatively reducing the amount of Ni in the surface region of an exposed surface other than the (003) plane improves capacity retention. This is presumed to be due to improved stability of the crystal planes through which insertion and extraction of lithium ions occur.

### 1. Primary Particles

The cathode active material of the present disclosure has crystalline primary particles that contain Li, Ni, Mn, and O. The composition of the primary particles will be described later.

The primary particles have, as a main phase, a crystal structure belonging to the space group R-3m. The term “main phase” refers to the crystal phase that gives the highest-intensity peak in X-ray diffraction (XRD) measurement using Cu Kα radiation. An example of crystal structures belonging to the space group R-3m is a layered rock-salt crystal structure.

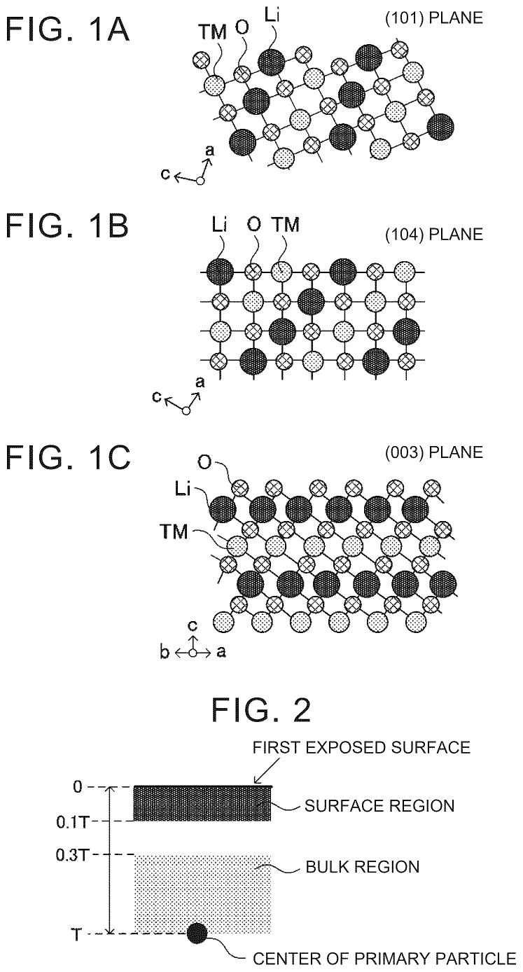

When observed with a transmission electron microscope, the primary particles have a first exposed surface other than the (003) plane. Examples of first exposed surfaces other than the (003) plane include a (101) plane as shown in FIG. 1A, and a (104) plane as shown in FIG. 1B. As shown in FIGS. 1A, 1B, and 1C, the (101) plane and the (104) plane differ from the (003) plane (FIG. 1C) in the orientation of layers of atoms (layers of Li atoms, O atoms, and transition metal (transition element) atoms), and therefore have different properties. In the (101) plane and the (104) plane, insertion and extraction of lithium ions occur during charge and discharge of the battery. On the other hand, in the (003) plane, insertion and extraction of lithium ions normally do not occur, and the (003) plane is maintained as a stable plane during charge and discharge. As will be described later, the primary particles may have a second exposed surface of the (003) plane.

In the primary particles of the present disclosure, the ratio of the Mn amount in the surface region of the first exposed surface to the Mn amount in the bulk region satisfies a predetermined relationship. Specifically, the Mn amount in the surface region of the first exposed surface is defined as X and the Mn amount in the bulk region located closer to the center of the primary particle than the surface region is defined Y, and X and Y satisfy 1.1≤X/Y.

The value X/Y may be 1.2 or more, 1.3 or more, 1.4 or more, or 1.5 or more. The value X/Y is, for example, 2.0 or less, and may be 1.9 or less, 1.8 or less, 1.7 or less, or 1.6 or less.

The surface region and the bulk region will now be described with reference to FIG. 2. As shown in FIG. 2, the position of the first exposed surface is defined as 0, and the distance from the first exposed surface to the center of the primary particle is defined as T (1.0 T). In this case, for example, the surface region may be a region located at a distance of 0 T or more and 0.2 T or less from the first exposed surface. The bulk region may be, for example, a region located at a distance of 0.3 T or more from the first exposed surface. As shown in FIG. 2, the bulk region may be a region that includes the center of the primary particle. In other words, the bulk region may be a region located at a distance of 0.3 T or more and 1.0 T or less from the exposed surface. The bulk region may be a region that does not include the center of the primary particle. For example, the bulk region may be a region located at a distance of 0.3 T or more and 0.9 T or less from the exposed surface.

The distances of the surface region and the bulk region from the first exposed surface vary depending on the particle size of the primary particle. For example, the surface region may be a region located at a distance of 0 nm or more and 5 nm or less from the first exposed surface. The bulk region may alternatively be a region located at a distance of 10 nm or more and 50 nm or less from the first exposed surface.

The Mn amount X in the surface region and the Mn amount Y in the bulk region can be measured as the peak intensities of Mn obtained by performing energy dispersive X-ray spectroscopy (EDX) analysis on the surface region and the bulk region. The ratio X/Y can be calculated as the ratio of those peak intensities. The Mn amount X may be the value measured at any single location in the surface region, or may be an average value measured at multiple locations in the surface region. The Mn amount Y may be the value measured at any single location in the bulk region, or may be an average value measured at multiple locations in the bulk region.

The primary particles may have the (003) plane as the second exposed surface. In this case, the amount of Mn in a surface region of the second exposed surface is defined as P, and the amount of Mn in a bulk region located closer to the center of the primary particle than the surface region is defined as Q. It is preferable that P and Q satisfy 0.95≤P/Q≤1.05. As described above, the (003) plane is normally maintained as a stable plane during charge and discharge of the battery. However, if the proportion of Mn in the surface region of the (003) plane is too low, that is, if the proportion of Ni is relatively too high, the Ni may transform into NiO, resulting in reduced stability of the (003) plane. Accordingly, it is presumed that, when P and Q satisfy 0.95≤P/Q≤1.05, the stability of the (003) plane can be improved and the capacity retention can further be enhanced.

The value P/Q may be 0.97 or more, 0.98 or more, or 0.99 or more. The value P/Q may be 1.03 or less, 1.01 or less, or 1.00 or less. Note that the value P/Q may be 1.00.

Regarding the surface region and the bulk region of the second exposed surface, the same description provided above for the first exposed surface can be applied to the second exposed surface by replacing “first” with “second.” The values P and Q can be measured in the same manner as X and Y described above.

The primary particles of the present disclosure contain Li, Ni, Mn, and O. The primary particles may contain these elements alone, or may contain additional elements. Examples of additional elements include transition elements other than Ni and Mn, metallic elements other than Li and transition elements (transition metals), and halogen elements such as F and Cl.

Examples of transition elements other than Ni and Mn include Ti, V, Cr, Fe, Co, Zr, Nb, La, and W. Examples of metallic elements include metals belonging to Groups 12 to 14 of the periodic table. Examples of metals belonging to Groups 12 to 14 include Zn, Al, Si, Ga, Ge, In, and Sn.

The composition of the primary particles is not particularly limited. One example is a composition represented by the general formula LiₓNiₐCo_{b}Mn_{c}O_{y} (where 0.1≤x≤1.5, 0.5≤a≤1.0, 0≤b≤0.3, 0<c≤0.3, a+b+c=1.0, and 1.5≤y≤2.1).

The value x may be 0.4 or more, 0.6 or more, 0.8 or more, 1.0 or more, or 1.05 or more. The value x may be 1.4 or less, or 1.2 or less.

The value y may be 1.6 or more, 1.7 or more, 1.8 or more, or 1.9 or more. The value y may be 2.0 or less.

The value a may be 0.6 or more, 0.7 or more, 0.8 or more, or 0.85 or more. The value a may be 0.9 or less.

The value c may be 0.01 or more, 0.03 or more, 0.05 or more, or 0.07 or more. The value c may be 0.25 or less, 0.20 or less, 0.15 or less, or 0.10 or less.

An example of the composition of the primary particles is LiNi_{0.93-0.97}Mn_{0.03-0.07}O₂. This corresponds to x=1, y=2, 0.93≤a≤0.97, b=0, and 0.03≤c≤0.05 in the above compositional formula. Since the above composition does not contain Co, it helps reduce cost and mitigate resource risks.

Other examples of the composition of the primary particles include LiNi_{0.95}Mn_{0.05}O₂, LiNi_{0.90}Mn_{0.10}O₂, LiNi_{0.5}Co_{0.2}Mn_{0.3}O₂, LiNi_{0.5}Co_{0.3}Mn_{0.2}O₂, LiNi_{0.5}Co_{0.4}Mn_{0.1}O₂, LiNi_{0.5}Co_{0.1}Mn_{0.4}O₂, LiNi_{0.6}Co_{0.2}Mn_{0.2}O₂, LiNi_{0.6}Co_{0.3}Mn_{0.1}O₂, LiNi_{0.6}CO_{0.1}Mn_{0.3}O₂, LiNi_{0.7}Co_{0.1}Mn_{0.2}O₂, LiNi_{0.7}Co_{0.2}Mn_{0.1}O₂, LiNi₀.&CO_{0.1}Mn_{0.1}O₂, and LiNi_{0.9}Co_{0.05}Mn_{0.05}O₂.

The composition of the primary particles can be determined by, for example, dissolving the cathode active material in an acid and measuring the resulting solution using inductively coupled plasma optical emission spectroscopy (ICP-OES).

The average particle size of the primary particles is, for example, 0.5 μm or more, and may be 0.6 μm or more, 0.8 μm or more, 1 μm or more, 2 μm or more, or 5 μm or more. The average particle size of the primary particles is, for example, 20 μm or less, and may be 15 μm or less, or 10 μm or less. The particle size of each primary particle can be obtained as, for example, the maximum diameter observed using a scanning electron microscope (SEM). For example, in the state of the battery described later, the particle size (maximum diameter) of each primary particle may be determined from a cross-sectional image of the cathode active material layer.

### 2. Cathode Active Material

The cathode active material of the present disclosure is typically a single-crystal active material formed of the primary particles described above. The term “single-crystal active material” refers to an active material that is not a polycrystalline active material (an active material that is a dense aggregate of numerous primary particles). A single-crystal active material is typically not aggregated and exists as independent particles. It is preferable that no grain boundaries be observed in a single-crystal active material in scanning electron microscope (SEM) observation (at a magnification of about 10,000× to about 30,000×). A single-crystal active material exhibits less degradation over time than a polycrystalline active material.

The average particle size of the cathode active material is, for example, greater than 0.5 μm and 30 μm or less, and may be 0.8 μm or more and 25 μm or less, 1 μm or more and 20 μm or less, or 2 μm or more and 15 μm or less. The cathode active material is, for example, in the form of particles.

The method for producing the cathode active material of the present disclosure is not particularly limited, and may be, for example, the method described in the Example below. The cathode active material of the present disclosure is used in a lithium-ion battery. A lithium-ion battery will be described below.

### B. Lithium-Ion Battery

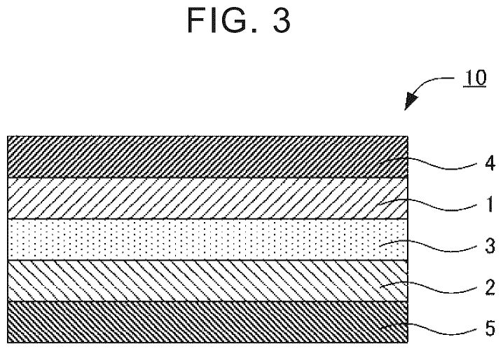

FIG. 3 is a schematic sectional view illustrating the lithium-ion battery according to the present disclosure. A lithium-ion battery 10 shown in FIG. 3 includes a cathode active material layer 1, an anode active material layer 2, an electrolyte layer 3 disposed between the cathode active material layer 1 and the anode active material layer 2, a cathode current collector 4 that collects electrons from the cathode active material layer 1, and an anode current collector 5 that collects electrons from the anode active material layer 2. The cathode active material layer 1 of the lithium-ion battery 10 contains the cathode active material of the present disclosure described above.

In the present disclosure, since the cathode active material described above is used, the lithium-ion battery exhibits good capacity retention.

### 1. Cathode Active Material Layer

The cathode active material layer contains the cathode active material described above. Since the details of the cathode active material are the same as those given in section “A. Cathode Active Material,” description thereof will be omitted.

The proportion of the cathode active material in the cathode active material layer is, for example, 20 mass % or more, and may be 30 mass % or more, or 40 mass % or more. If the proportion of the cathode active material is too low, sufficient energy density may not be obtained. The proportion of the cathode active material in the cathode active material layer is, for example, 95 mass % or less, and may be 70 mass % or less, or 60 mass % or less. If the proportion of the cathode active material is too high, the ionic conductive properties and electronic conductive properties of the cathode active material layer may relatively decrease.

The cathode active material layer may contain an electrically conductive material. The addition of an electrically conductive material improves the electronic conductive properties. Examples of electrically conductive materials include carbon-based electrically conductive materials, metal particles, and electrically conductive polymers. Examples of carbon-based electrically conductive materials include particulate materials such as acetylene black (AB) and Ketjenblack (KB), and fibrous materials such as vapor-grown carbon fibers (VGCFs), carbon nanotubes (CNTs), and carbon nanofibers (CNFs). The proportion of the electrically conductive material in the cathode active material layer is, for example, 0.1 mass % or more and 5 mass % or less. If the proportion of the electrically conductive material is too low, there may not be sufficient electron conduction paths. If the proportion of the electrically conductive material is too high, the proportion of the cathode active material relatively decreases, which may lower the energy density.

The cathode active material layer may contain a binder. Examples of binders include rubber-based binders such as styrene-butadiene rubber (SBR) and butadiene rubber (BR), polycarboxylic-acid-based binders such as carboxymethyl cellulose, and fluoride-based binders such as polyvinylidene fluoride (PVdF). The proportion of the binder in the cathode active material layer is, for example, 0.5 mass % or more and 15 mass % or less.

The cathode active material layer may contain an electrolyte. The electrolyte is described in section “3. Electrolyte Layer” below. The thickness of the cathode active material layer is, for example, 0.1 μm or more and 1000 μm or less.

### 2. Anode Active Material Layer

The anode active material layer contains at least an anode active material. Examples of anode active materials include carbon-based active materials, Li-based active materials, Si-based active materials, and oxide-based active materials.

Examples of carbon-based active materials include graphite, soft carbon, and hard carbon. The graphite may be either natural graphite or artificial graphite. Examples of Li-based active materials include Li and Li alloys. Examples of Li alloys include Li—Si alloys. Examples of Si-based active materials include Si, SiC composite active materials, Si alloys, and silicon oxides. Examples of SiC composite active materials include active materials in which Si or an Si alloy is supported on a carbon support. Examples of oxide-based active materials include lithium titanate such as Li₄Ti₅O₁₂.

The proportion of the anode active material in the anode active material layer is, for example, 20 mass % or more, and may be 30 mass % or more, or 40 mass % or more. If the proportion of the anode active material is too low, sufficient energy density may not be obtained. The proportion of the anode active material in the anode active material layer is, for example, 95 mass % or less, and may be 70 mass % or less, or 60 mass % or less. If the proportion of the anode active material is too high, the ionic conductive properties and electronic conductive properties of the anode active material layer may relatively decrease.

The anode active material layer may contain at least one selected from an electrically conductive material, a binder, and an electrolyte. The details of the electrically conductive material, binder, and electrolyte are the same as those described in section “1. Cathode Active Material Layer.” The thickness of the anode active material layer is, for example, 0.1 μm or more and 1000 μm or less.

### 3. Electrolyte Layer

The electrolyte layer is a layer disposed between the cathode active material layer and the anode active material layer, and contains at least an electrolyte. The electrolyte is, for example, a liquid electrolyte (electrolyte solution).

An example of the electrolyte solution is a non-aqueous electrolyte solution. A non-aqueous electrolyte solution contains, for example, a lithium salt and a non-aqueous solvent. Examples of lithium salts include inorganic lithium salts such as LiPF₆, LiBF₄, LiClO₄, and LiAsF₆, and organic lithium salts such as LiCF₃SO₃, LiN(SO₂CF₃)₂, LiN(SO₂C₂F₅)₂, and LiC(SO₂CF₃)₃.

Examples of non-aqueous solvents include carbonate-based solvents such as ethylene carbonate (EC), propylene carbonate (PC), butylene carbonate (BC), dimethyl carbonate (DMC), diethyl carbonate (DEC), and ethyl methyl carbonate (EMC). The non-aqueous solvent may be a mixture of a cyclic carbonate having a high dielectric constant and high viscosity, such as EC or PC, and a chain carbonate having a low dielectric constant and low viscosity, such as DMC, DEC, or EMC. The concentration of the lithium salt in the non-aqueous electrolyte solution is, for example, 0.3 M or more and 5 M or less. The non-aqueous electrolyte solution may contain an ionic liquid. Examples of ionic liquids include sulfonium salts, ammonium salts, pyridinium salts, piperidinium salts, pyrrolidinium salts, morpholinium salts, phosphonium salts, and imidazolium salts.

Another example of the electrolyte solution is an aqueous electrolyte solution. An aqueous electrolyte solution is an electrolyte solution containing water as a main component of the solvent. The proportion of water relative to the total solvent is, for example, 50 mass % or more, and may be 70 mass % or more. Examples of lithium salts used in the aqueous electrolyte solution include imide-based electrolytes such as lithium bis(fluorosulfonyl)imide and lithium bis(trifluoromethanesulfonyl)imide. The concentration of the lithium salt in the aqueous electrolyte solution is, for example, 1 M or more and 25 M or less.

The electrolyte layer may include a separator impregnated with the electrolyte solution described above. The separator material may be a conventionally known material. The electrolyte layer may contain a solid electrolyte. Examples of solid electrolytes include organic solid electrolytes such as polymer electrolytes and gel electrolytes, and inorganic solid electrolytes such as sulfide solid electrolytes, oxide solid electrolytes, and halide solid electrolytes.

### 4. Lithium-Ion Battery

The lithium-ion battery of the present disclosure preferably includes a cathode current collector that collects current from the cathode active material layer, and an anode current collector that collects current from the anode active material layer. Examples of materials for the cathode current collector include stainless steel (steel use stainless (SUS)), aluminum, nickel, iron, titanium, and carbon. Examples of materials for the anode current collector include SUS, copper, nickel, and carbon. The battery of the present disclosure may include an outer casing that houses a power-generating element (the cathode active material layer, the electrolyte layer, and the anode active material layer). Examples of outer casings include case-type casings and laminate-type casings.

The lithium-ion battery of the present disclosure may be either a primary battery or a secondary battery, but is preferably a secondary battery. This is because a secondary battery can be repeatedly charged and discharged and is therefore useful as, for example, an in-vehicle battery. Examples of applications of lithium-ion batteries include power sources for vehicles such as hybrid electric vehicles (HEVs), plug-in hybrid electric vehicles (PHEVs), battery electric vehicles (BEVs), gasoline vehicles, and diesel vehicles. In particular, lithium-ion batteries are preferably used as traction power sources for HEVs, PHEVs, or BEVs. Lithium-ion batteries may also be used as power sources for moving objects other than vehicles (for example, trains, ships, and aircraft), and as power sources for electrical products such as information processing devices.

Note that the present disclosure is not limited to the above embodiment. The above embodiment is merely illustrative, and any structure having substantially the same configuration as, and having similar functions and effects to, the technical idea described in the claims of the present disclosure is included in the technical scope of the present disclosure.

### Example 1

### Preparation of Cathode Active Material

### Preparation of Aqueous Raw Material Solution

NiSO₄ and MnSO₄ were prepared as raw materials, and these materials were dissolved in deionized water to prepare an aqueous raw material solution. The molar ratio of Ni and Mn in the aqueous raw material solution was adjusted to Ni:Mn=95:5. The concentration of the aqueous raw material solution (the proportion of all the raw materials in the aqueous raw material solution) was 20 mass %.

### Dehydration and Pre-Calcination

A certain amount of aqueous NH₃ solution was placed in a reaction vessel, and while stirring with a stirrer, the inside of the reaction vessel was purged with nitrogen. An aqueous NaOH solution was then added to the reaction vessel, and while maintaining the pH at an alkaline level (pH=12) and keeping the temperature constant, the aqueous raw material solution and the aqueous NH₃ solution were added dropwise into the reaction vessel to precipitate a transition metal hydroxide. After completion of the precipitation reaction, the precipitate was subjected to dehydration and pre-calcination under the following temperature and pressure conditions.
Temperature: 120° C.
Time: four hours
Pressure: 0.2 MPa

### Recovery of Precursor

After the pre-calcination, the precipitate was washed with water. The washed precipitate was filtered to recover the transition metal hydroxide. The recovered transition metal hydroxide was then dried at 110° C. for 12 hours to evaporate moisture (to obtain a dried material). A precursor was thus prepared.

### Mixing of Li Raw Material

The obtained precursor (transition metal hydroxide) and a lithium compound (LiOH) serving as an Li source were mixed such that the molar ratio of Li to the total amount of transition metal species contained in the transition metal hydroxide was 1.6.

### Calcination

The resulting mixture was subjected to heat treatment (calcination). Specifically, the mixture was first calcinated at 500° C. for three hours and then at 780° C. for 12 hours in a muffle furnace. Next, the obtained calcined product was ground in an agate mortar to a particle size of 0.2 mm or less, dispersed in 500 mL of pure water, and vigorously stirred for one minute to obtain a slurry. The slurry was filtered through a Büchner funnel with filter paper and rinsed with 500 mL of pure water, and the resulting cake was vacuum-dried at 90° C. The obtained dried powder was calcined (post-annealed) at 500° C. for three hours under an oxygen flow. The resulting calcined product was pulverized in an agate mortar and further disaggregated to a predetermined particle size (pulverization). A cathode active material formed of primary particles having a composition represented by LiNi_{0.95}Mn_{0.05}O₂ was thus obtained.

### Fabrication of Battery

A slurry for forming a cathode active material layer, namely a slurry containing above cathode active material and N-methyl-2-pyrrolidone (NMP) serving as a solvent, was applied onto a metal foil serving as a cathode current collector using a film applicator with a thickness adjustment function (manufactured by Allgood Co., Ltd.). After coating, the coated metal foil was dried on a hot plate at 80° C. for five minutes to evaporate the NMP solvent, thereby forming a cathode active material layer on the cathode current collector. A cathode including the cathode current collector and the cathode active material layer was thus obtained.

An anode composite paste containing natural graphite as an anode active material was applied onto the surface of a metal foil serving as an anode current collector using a film applicator with a thickness adjustment function (manufactured by Allgood Co., Ltd.). The coated metal foil was then dried at 80° C. for five minutes in a dryer. An anode having an anode active material layer on the anode current collector was thus prepared. A 1 M LiPF₆ solution containing LiPF₆ as an electrolyte and ethylene carbonate (EC), dimethyl carbonate (DMC), and ethyl methyl carbonate (EMC) as solvents in a volume ratio of EC/DMC/EMC=3/4/3 vol % was prepared as an electrolyte solution. The cathode, a separator, and the anode were stacked, the separator was impregnated with the electrolyte solution, and a small laminate cell was fabricated in which the power-generating element was housed in an Al laminate film pouch.

### Comparative Example 1

In preparing the aqueous raw material solution, NiSO₄, CoSO₄, and MnSO₄ were used as raw materials. The molar ratio of Ni, Co, and Mn in the aqueous raw material solution was adjusted to Ni:Co:Mn=90:5:5.

In the calcination, the mixture was first calcined at 500° C. for three hours, and then at 860° C. for 12 hours.

Except for these differences, a cathode active material formed of primary particles having a composition represented by LiNi_{0.90}Co_{0.05}Mn_{0.05}O₂ was prepared and a cell (small laminate cell) was fabricated in the same manner as in Example 1.

### Evaluation

### STEM-EDX Analysis

Scanning transmission electron microscopy-energy dispersive X-ray spectroscopy (STEM-EDX) analysis was performed as described below to determine whether the primary particles had the first exposed surface specified in the present disclosure (the exposed surface other than the (003) plane that satisfies 1.1≤X/Y). The results are shown in Table 1. The surface region was defined as a region located at a distance of 0 nm or more and 5 nm or less from the exposed surface. The bulk region was defined as a region located at a distance of 10 nm or more and 50 nm or less from the exposed surface. The average Mn amounts in these regions were obtained as the Mn amount X and the Mn amount Y, respectively, and the ratio X/Y was calculated.

The prepared cathode active materials were subjected to pretreatment by a plasma focused ion beam (plasma FIB) method. Helios 5 Hydra manufactured by Thermo Fisher Scientific Inc. was used for the pretreatment. The pretreatment was carried out under an Ar gas atmosphere. After the pretreatment, STEM-EDX analysis was performed on the cathode active materials.
Scanning transmission electron microscope (STEM) observation was conducted using JEM-ARM200F Dual-X manufactured by JEOL Ltd. The acceleration voltage was set to 200 kV, and the beam diameter was set to 0.2 nm.
EDX analysis was performed using JED-2300 manufactured by JEOL Ltd. (NORAN System 7 manufactured by Thermo Fisher Scientific Inc.). The collection solid angle was 1.96 sr.

### Cycle Test

A cycle test was conducted on the laminate cells under the following conditions.
Ambient temperature: 60° C.
Number of cycles: 100
Current rate: 0.3 C
Voltage range: 4.25 V to 2.5 V

In the cycle test, the initial discharge capacity (mAh) obtained during the discharge process of the first charge-discharge cycle was divided by the weight (g) of the cathode active material contained in the electrode of the laminate cell to calculate the initial discharge capacity per gram of cathode active material (mAh g⁻¹). Similarly, the discharge capacity (mAh g⁻¹) after 100 cycles was calculated. The ratio (%) of the discharge capacity after 100 cycles to the initial discharge capacity was calculated as the capacity retention. The results are shown in Table 1.

TABLE 1

| | | Initial | Discharge | |
|---|---|---|---|---|
| | First Exposed | Discharge | Capacity After | Capacity |
| | Surface | Capacity | 100 Cycles | Retention |
| | (1.1 ≤ X/Y) | (mAh g⁻¹) | (mAh g⁻¹) | (%) |
| Example 1 | Present | 211 | 179 | 85 |
| Comparative | Absent | 217 | 143 | 66 |
| Example 1 | | | | |

As shown in Table 1, although the initial discharge capacities of Example 1 and Comparative Example 1 were substantially the same, the discharge capacity after 100 cycles was higher in Example 1, and the capacity retention was also better in Example 1. These results confirmed that the cathode active material of the present disclosure can improve the capacity retention of a battery. Half-cells having a cathode active material layer were fabricated using the cathode slurries prepared in Example 1 and Comparative Example 1, and a detailed comparison of their initial discharge capacities was conducted. The half-cell of Example 1 exhibited a better initial discharge capacity than the half-cell of Comparative Example 1.

What is claimed is:

1. A cathode active material for use in a lithium-ion battery, the cathode active material comprising primary particles that are crystalline, the primary particles containing Li, Ni, Mn, and O, wherein:
the cathode active material is a single-crystal active material constituted of the primary particles;
the primary particles have, as a main phase, a crystal structure belonging to space group R-3m;
when observed with a transmission electron microscope, the primary particles have a first exposed surface other than a (003) plane; and
an amount of Mn in a surface region of the first exposed surface is defined as X and an amount of Mn in a bulk region located closer to a center of the primary particle than the surface region is defined as Y, and X and Y satisfy 1.1≤X/Y.

2. The cathode active material according to claim 1, wherein:
when observed with a transmission electron microscope, the primary particles have a second exposed surface of the (003) plane; and
an amount of Mn in a surface region of the second exposed surface is defined as P and an amount of Mn in a bulk region located closer to the center of the primary particle than the surface region is defined as Q, and P and Q satisfy 0.95≤P/Q≤1.05.

3. The cathode active material according to claim 1, wherein X and Y satisfy X/Y≤2.0.

4. The cathode active material according to claim 1, wherein an average particle size of the primary particles is 0.5 μm or more.

5. The cathode active material according to claim 1, wherein the primary particles have a composition represented by LiₓNiₐCo_{b}Mn_{c}O_{y} (where 0.1≤x≤1.5, 0.5≤a≤1.0, 0≤b≤0.3, 0<c≤0.3, a+b+c=1.0, and 1.5≤y≤2.1).

6. A lithium-ion battery comprising:
a cathode active material layer;
an anode active material layer; and
an electrolyte layer disposed between the cathode active material layer and the anode active material layer,
wherein the cathode active material layer contains the cathode active material according to claim 1.
